(19) United States
(12) Patent Application Publication
(10) Pub. No.: US 2014/0042515 A1
(43) Pub. Date: Feb. 13, 2014

(54) HIGH VOLTAGE DEVICE

(71) Applicants: Pei-Kai Tseng, Keelung City (TW); Chien-Fu Tang, Hsinchu City (TW); Issac Y. Chen, Zhubei City (TW)

(72) Inventors: Pei-Kai Tseng, Keelung City (TW); Chien-Fu Tang, Hsinchu City (TW); Issac Y. Chen, Zhubei City (TW)

(73) Assignee: Richtek Technology Corporation

(21) Appl. No.: 13/569,085

(22) Filed: Aug. 7, 2012

(51) Int. Cl. H01L 29/788

(52) U.S. Cl. 257/315; 257/E29.3

(57) ABSTRACT

The present invention provides a high voltage device including a shielding metal layer to reduce the noise interference from a high voltage source. The high voltage device includes a substrate, a field oxide layer, a gate layer, a shielding metal layer, and a high voltage interconnection line. The substrate includes a first doped region and a second doped region separated from each other. The field oxide layer is disposed on the substrate. The gate layer is disposed above the field oxide layer. The high voltage interconnection line is coupled to the first doped region and passes above but not below the first shielding metal layer.

### BACKGROUND OF THE INVENTION

1. Field of Invention

The present invention relates to a high voltage device, especially a high voltage device including a shielding metal layer to reduce the noise interference from a high voltage source.

2. Description of Related Art

High voltage device is commonly used in various industrial applications, such as voltage converters, motor driving circuits, LED driving circuits, etc. Because one terminal (source or drain) of the high voltage device is coupled to a high voltage source, it is preferred that the voltage level on a connection line between the terminal and the high voltage source gradually descends from the high voltage source to the terminal. FIG. 1 shows a cross section view of a prior art high voltage device 10, wherein the high voltage device 10 includes a semiconductor region 11, a plurality of floating electrodes 12 formed by a first metal layer, a plurality of floating gates 13, a drain 14, a source 15, a field oxide 15, a plurality of P-type channel stop doped regions 17, and a high voltage interconnection line 18 formed by a higher metal layer, wherein the plural floating electrodes 12 and the plural floating gates 13 are provided so that the voltage level descends by capacitive coupling effect, and the P-type channel stop doped regions 17 are provided to equivalently increase the channel length. By the capacitive coupling effect of the extension structure of the plural floating electrodes 12 and the plural floating gates 13, the prior art high voltage device 10 causes the voltage level the high voltage interconnection line 18 to descend uniformly. For related technique details, please refer to U.S. Pat. No. 7,309,894; US 2008/0203496; US 2009/0039425; US 2011/0233716; U.S. Pat. No. 5,446,300.

However, the aforementioned high voltage device 10 has a complicated structure which involves higher fabrication cost and difficult quality control. In view of these drawbacks, the present invention provides a high voltage device with simpler structure, which has good operation characteristics.

### SUMMARY OF THE INVENTION

The present invention provides to a high voltage device, especially a high voltage device including a shielding metal layer to reduce the noise interference from a high voltage source, with benefits of simple structure and good operation characteristics.

The other purposes and benefits of the present invention can be better understood from the detailed description below.

For the above or other purposes, the present invention provides a high voltage device which includes a substrate, a field oxide layer, a gate layer, a shielding metal layer, and a high voltage interconnection line. The substrate includes a first doped region and a second doped region which are separated from each other. The field oxide layer is disposed on the substrate and between the first doped region and the second doped region. The gate layer is disposed above the field oxide layer. The high voltage interconnection line is coupled to the first doped region and passes above but not below the first shielding metal layer.

In an embodiment, the high voltage device can further include a second shielding metal layer. The second shielding metal layer is disposed between the first shielding metal layer and the high voltage interconnection line, and the second shielding metal layer is disposed above a part of the first shielding metal layer but not directly beneath the high voltage interconnection line. The second shielding metal layer is preferably coupled to a ground or the gate layer.

In a preferable embodiment of the present invention, the width of the high voltage interconnection line is less than 5 micrometer.

In a preferable embodiment of the present invention, the high voltage device includes an interconnection. The closest distance (S′) between the high voltage interconnection line and the low voltage portion of the interconnection, and the distance (T) between the high voltage interconnection and the first shielding metal layer, meet the following relation: 2T≧S′≧T.

In a preferable embodiment of the present invention, the closest distance (S) between the high voltage interconnection line and the second shielding metal layer, and the distance (T) between the high voltage interconnection line and the first shielding metal layer, meet the following relation: 2T≧S≧T.

In a preferable embodiment of the present invention, no channel stop doped region is disposed below the field oxide region.

In another preferable embodiment of the present invention, at least one floating gate having a floating voltage level is disposed above the field oxide layer and at same elevation level as the gate layer.

The objectives, technical details, features, and effects of the present invention will be better understood with regard to the detailed description of the embodiments below, with reference to the drawings.

### BRIEF DESCRIPTION OF THE DRAWINGS

FIG. 1 shows a cross section view according to a prior art high voltage device.

FIG. 2 shows a preferable embodiment of the high voltage device according to the present invention.

FIG. 3 shows a cross section view of the high voltage device taken along the AA cross section line shown in FIG. 2.

FIG. 4 shows a schematic diagram of the high voltage device according to a preferred embodiment of the present invention.

FIG. 5 shows a cross section view of the high voltage device taken along the BB cross section line shown in FIGS. 2 and 3.

FIG. 6 shows a cross section view of another preferred embodiment of the high voltage device according to the present invention.

FIG. 7 shows a cross section view of the high voltage device taken along the BB cross section line shown in FIGS. 2 and 6.

FIGS. 8 and 9 show two other preferable embodiments of the high voltage device according to the present invention.

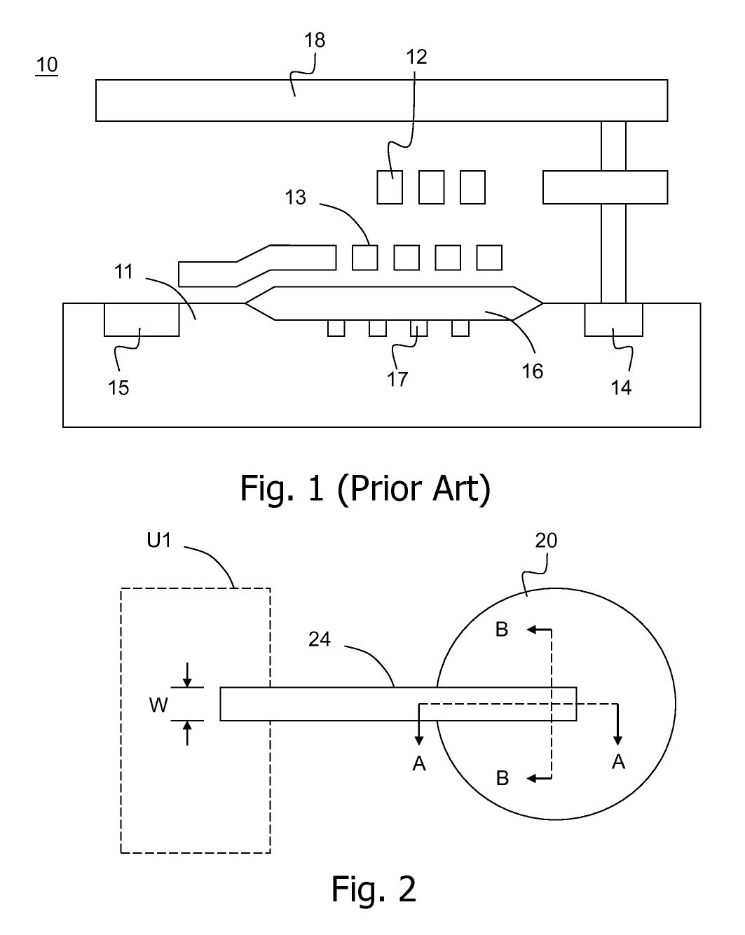

### DESCRIPTION OF THE PREFERRED EMBODIMENTS

The drawings as referred to throughout the description of the present invention are for illustrative purpose only, but not drawn according to actual scale, shape, thickness, width, distance, etc.

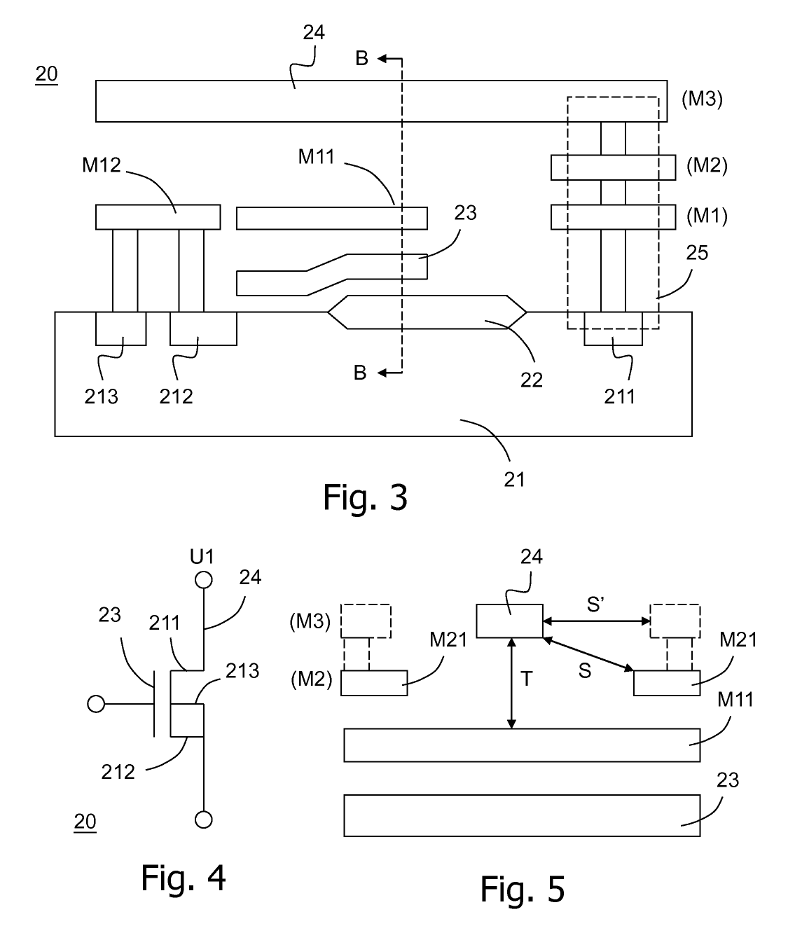

Referring to FIGS. 2 and 3, a preferred embodiment of a high voltage device 20 according to the present invention is shown. As shown in FIG. 2, a high voltage source U1 is provided, and a high voltage interconnection line 24 connects the high voltage device 20 and the high voltage source U1. FIG. 3 shows a cross section view of the high voltage device 20 according to the AA cross section line shown in FIG. 2. The high voltage device 20 includes a substrate 21, a field oxide layer 22, a gate layer 23, a first metal layer M1 (including a first interconnection metal layer M12 and a first shielding metal layer M11 disposed above the gate layer 23), a high voltage interconnection line 24 formed by a higher metal layer, and a conducting structure 25. In order to simplify the diagram, the dielectric layers between the conductive layers are omitted.

The substrate 21 includes a first doped region 211 and a second doped region 212 which are separated from each other. The first doped region 211 and the second doped region 212 for example can respectively be a source and a drain of the high voltage device 20. The substrate 21 can further include a third doped region 213, which can be a body electrode of the high voltage device 20, and the third doped region 213 has an opposite conductivity to the first doped region 211 and the second doped region 212. The field oxide 22 is disposed above the substrate 21 and between the first doped region 211 and the second doped region 212. The gate layer 23 is disposed above the field oxide 22. The first shielding metal M11 is disposed above and coupled to the gate layer 23 (the connecting plug in between is not shown in figure) . The high voltage interconnection line 24 is coupled to the first doped region 211 through the conducting structure 25, and the high voltage interconnection line 24 passes above but not below the first shielding metal layer M11 (that is, the first shielding metal layer M11 is disposed between the gate layer 23 and the high voltage interconnection line 24).

In this embodiment, the high voltage interconnection line 24 is formed by a higher metal layer such as a third metal layer (M3), and the conducting structure 25 includes a part of a first metal layer (M1), a part of a second metal layer (M2), and conducting plugs connecting them; however, this is only an example which should not be taken as limitations on the present invention. It will be understood from the later description that the high voltage device 24 does not need to be exactly the third metal layer but can be any metal layer at or above the second metal layer, as long as a suitable distance is provided between the high voltage interconnection line 24 and the first shielding metal layer M11. Further, the term “metal layer” is used according to customary terminology in CMOS wafer fabrication. In fact, the metal layer does not have to be pure metal, but can be any conductive layer with good conductivity, such as doped polysilicon, metal, alloy, metal compound, or a combination thereof. Therefore, in the context of the present invention, the term “metal layer” can be taken as a synonym of “conductive layer”.

In a preferable embodiment, the width of the high voltage interconnection line shown in FIG. 2 is preferably less than 10 micrometer, and more preferably less than 5 micrometer.

FIG. 4 is a circuit diagram showing an application example of the high voltage device 20 as an NMOS transistor, wherein the firs doped region 211 and the second doped region 212 are the drain and the source of the NMOS transistor, respectively, and the gate layer 23 is the gate of the NMOS transistor for receiving a gate control signal. The high voltage interconnection line 24 connects the drain of the high voltage device 20 and the high voltage source U1, and a capacitive coupling effect is formed between the high voltage interconnection line 24 and the first shielding metal layer M11 so that the voltage level on the high voltage interconnection line 24 gradually descends. Besides, the first shielding metal layer M11 can shield the gate layer 23 to avoid malfunction of the gate or noise due to the high voltage interconnection line 24.

In this embodiment, the first doped region 211 and the second doped region 212 are N-type doped regions, and the third doped region 213 is P-type doped region. In another embodiment, the high voltage device 20 can be a PMOS transistor, wherein the first doped region 211 and the second doped region 212 are P-type doped regions, and the third doped region 213 is N-type doped region.

FIG. 5 shows a cross section view of the high voltage device 20 taken along the BB cross section line shown in FIGS. 2 and 3, and FIG. 5 also shows preferable relationships among layers. As shown in the figure, there is a vertical distance T between the high voltage interconnection line 24 and the first shielding metal layer M11, and this vertical distance T can be determined according to application requirement of the device; in a preferable embodiment, the vertical distance T is determined such that the breakdown voltage of the high voltage device 20 is greater than 600V. Furthermore, the closest distance S′ or S between the high voltage interconnection line 24 and the low voltage portion of the interconnection (the third metal layer M3 is shown by dash line because in some applications there might not be any part of the interconnection located at the level of the third metal layer M3) preferably meets the following relation: 2T≧S′≧T or 2T≧S≧T.

Still referring to FIG. 5, preferably, a second shielding metal layer M21 is disposed above the first shielding metal layer M11 and at a distance S from the high voltage interconnection line 24; the second shielding metal layer M21 further helps to avoid malfunction or reduce the influence of noises. In one embodiment, the second shielding metal layer M21 can be connected to ground, and as shown in figure but not to be taken as a limiting example, the second shielding metal layer M21 can be electrically connected to the third metal layer M3. The second shielding metal layer M21 is disposed between the high voltage interconnection line 24 and the first shielding metal layer M11, and the second shielding metal layer M21 is above a part of the first shielding metal layer M11 but not directly beneath the high voltage interconnection line 24.

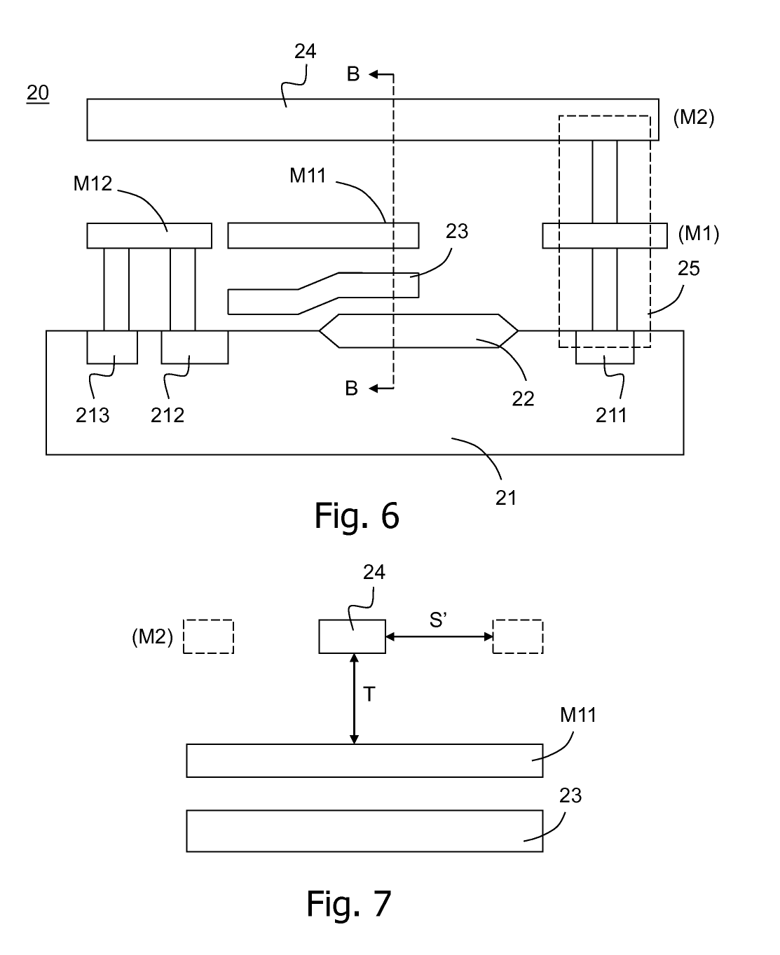

FIGS. 6 and 7 show a second preferable embodiment of the present invention. In the previous embodiment, the high voltage interconnection line 24 is formed by the third metal layer (M3) for the purpose of providing a suitable distance T. In this embodiment, the high voltage interconnection line 24 is formed by the second metal layer (M2), because there is enough distance between the first metal layer (M1) and the second metal layer (M2). Referring to FIG. 7, similarly, the distance S′ between the high voltage interconnection line 24 and other low voltage parts preferably meets the following relation: 2T≧S′≧T.

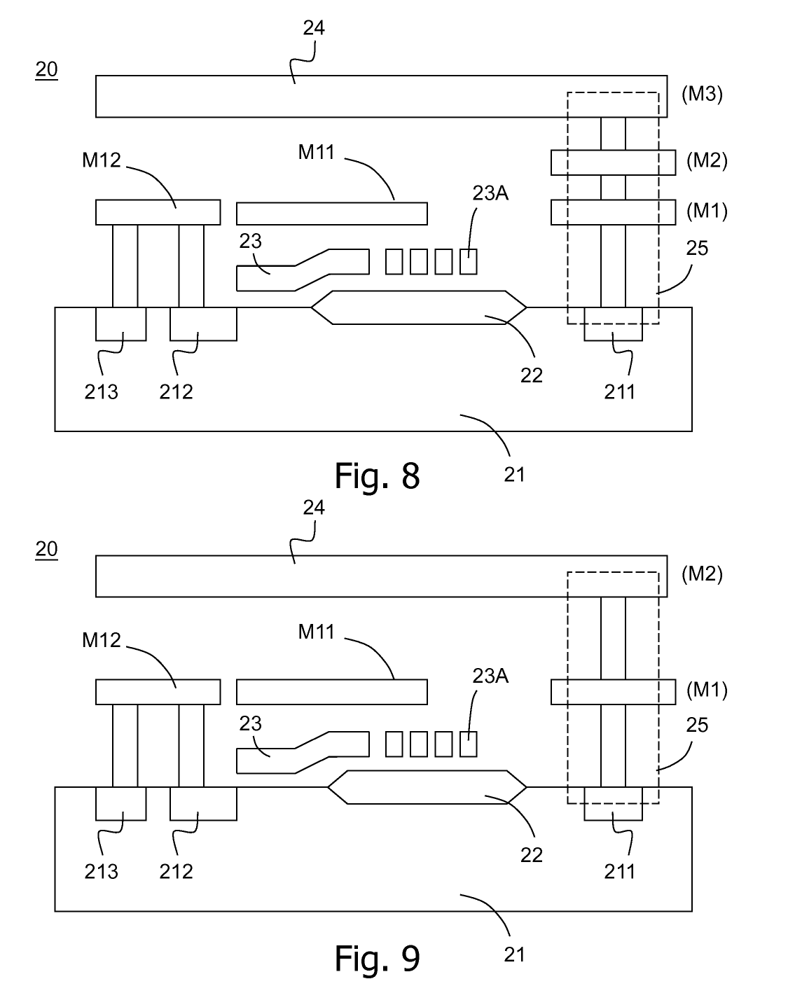

FIGS. 8 and 9 respectively show other two embodiments, wherein besides the gate layer 23, optionally, at least one floating gate 23A is disposed above the field oxide 22 and at same elevation level as the gate layer 23; the floating gate 23A is made of polysilicon or metal, and its voltage level is floating. The floating gate 23A can reduce coupling effect to the field oxide.

In comparison with the prior art, the present invention has a simpler structure wherein the floating electrodes, the floating gates, and the channel stop doped regions below the field oxide are not necessary (however, though they are not necessary, they can be optionally provided). Moreover, the first shielding metal layer M11 provides two effects that first, it causes the voltage on the high voltage interconnection line 24 to descend uniformly, and second, it protects the gate layer 23 to avoid malfunction or to shield the gate layer 23 from influence by noises.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. An embodiment or a claim of the present invention does not need to achieve all the objectives or advantages of the present invention. The title and abstract are provided for assisting searches but not for limiting the scope of the present invention.

What is claimed is:

1. A high voltage device, comprising:
a substrate, including a first doped region and a second doped region which are separated from each other;
a field oxide layer, disposed on the substrate and between the first doped region and the second doped region;
a gate layer, disposed partially above the field oxide layer;
a first shielding metal layer, disposed above the gate layer; and
a high voltage interconnection line, coupled to the first doped region and passing above but not below the first shielding metal layer.

2. The high voltage device of claim 1, wherein the first doped region and the second region are a drain and a source of a MOS transistor, respectively.

3. The high voltage device of claim 1, further including a second shielding metal layer disposed between the first shielding metal layer and the high voltage interconnection line, wherein the second shielding metal layer is disposed above a part of the first shielding metal layer but not directly beneath the high voltage interconnection.

4. The high voltage device of claim 3, wherein the second shielding metal layer is coupled to a ground or the gate layer.

5. The high voltage device of claim 3, wherein the first shielding metal layer and the second shielding metal layer are made of a material selected from doped polysilicon, metal, alloy, metal compound, and a combination of two or more of the above.

6. The high voltage device of claim 1, wherein the width of the high voltage interconnection line is less than 5 micrometer.

7. The high voltage device of claim 1, further including an interconnection, wherein a closest distance (S′) between the high voltage interconnection line and the interconnection and a distance (T) between the high voltage interconnection line and the first shielding metal layer meet following relation: 2T≧S′≧T.

8. The high voltage device of claim 3, wherein a closest distance (S) between the high voltage interconnection line and the second shielding metal layer and a distance (T) between the high voltage interconnection line and the first shielding metal layer meet the following relation: 2T≧S≧T.

9. The high voltage device of claim 3, wherein no channel stop doped region is disposed below the field oxide region.

10. The high voltage device of claim 1, further comprising a third doped region, wherein the third doped region is adjacent to the second doped region and includes an opposite conductivity to the second doped region.

11. The high voltage device of claim 1, further comprising at least one floating gate having a floating voltage level, which is disposed above the field oxide layer and at same elevation level as the gate layer.
